(19) United States
(12) Patent Application Publication
(10) Pub. No.: US 2008/0197377 A1
(43) Pub. Date: Aug. 21, 2008

(54) PHOTONIC SEMICONDUCTOR DEVICE AND MANUFACTURING METHOD

(75) Inventors: Hisao SUDO, Kawasaki (JP); Tsuyoshi YAMAMOTO, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/032,250

(22) Filed: Feb. 15, 2008

(30) Foreign Application Priority Data
Feb. 16, 2007 (JP) 2007-036645

(51) Int. Cl. H01L 33/00

(52) U.S. Cl. 257/99; 438/39; 257/E33.006

(57) ABSTRACT

A photonic semiconductor device which includes a semiconductor layer having a ridge-form protruding part formed on a semiconductor substrate. A resin layer is formed on surface parts on both sides of the protruding part so that the protruding part is embedded, and a first insulating film includes an opening that is formed on the resin layer which exposes an upper surface of the protruding part and a portion of a upper surface of the resin layer on both sides of the protruding part. A first electrode is formed in the opening so as to cover the upper surface of the protruding part, and electrically couple to an upper part of the protruding part; and a second electrode, which electrically couples to the first electrode, is formed on the first electrode and the first insulation film.

### CROSS-REFERENCE TO RELATED APPLICATION

This application is based upon and claims the benefit of priority from the prior Japanese Patent Application No. 2007-036645 filed on Feb. 16, 2007, the entire contents of which are incorporated herein by reference.

### BACKGROUND OF THE INVENTION

1. Field of the Invention

The present invention relates to a photonic semiconductor device and a manufacturing method.

2. Description of Related Art

In ridge-type photonic semiconductor devices which include a ridge-form semiconductor layer, embedding of the ridge structure in a resin such as benzocyclobutane (BCB) is performed.

FIG. 1 shows a structure of a conventional ridge-type photonic semiconductor device. A semiconductor layer 102 including an active layer 106 is formed on an N-type semiconductor substrate 100. The semiconductor layer 102 is processed to form a ridge, thereby forming a protruding ridge part 104. An active layer 106 is included in the ridge part 104. A P-type contact layer 108 is formed on the ridge part 104. A passivation film 110 is formed so as to cover the ridge part 104 on the semiconductor layer 102 where the ridge part 104 is formed. A resin layer 112 made up of BCB resin is formed on the semiconductor layer 102 on which the passivation film 110 is formed on both sides of the ridge part 104. The ridge part 104 is thereby further embedded in the resin layer 112. A silicon oxide film 114 is formed on the passivation film 110, the upper surface of the resin layer 112 and the ridge part 104 using a SOG (Spin On Glass) method. A contact hole 116 reaching the P-type contact layer 108 is formed in the silicon oxide film 114 and the passivation film 110 on the ridge part 104. A P-type electrode 118 connecting to the P-type contact layer 108 via the contact hole 116 is formed on the silicon oxide film 114 in which the contact hole 116 is formed. The P-type electrode 118 has a layer structure in which the lowest layer is a Ti film.

In a manufacturing process for the photonic semiconductor device shown in FIG. 1, the contact hole 116 is formed by etching with a resist pattern as a mask. This resist pattern is removed by O₂ ashing after formation of the contact hole 116. At this point, if the silicon oxide film 114 is not formed by the SOG method on the resin layer 112, the O₂ ashing oxidizes the resin layer 112 causing the resin layer 112 to deteriorate. As a result, the adhesiveness of the P-type electrode 118 formed on the resin layer 112 is reduced, making it easier for peeling of the electrode to occur.

However, by forming the silicon oxide film 114 on the resin layer 112 using the SOG method, deterioration of the resin layer 112 due to oxidation is prevented. This technique is employed to prevent the occurrence of electrode peeling. Since the adhesiveness between the silicon oxide film 114 and the electrode 118 is favorable, peeling in the photonic semiconductor device having the ridge part 104 embedded in the resin layer 112 can be prevented.

The ridge-type photonic semiconductor device generally has a ridge part whose upper surface is, at a few μm, very narrow. Therefore, to form a contact hole which is entirely within the ridge part, the width of the contact hole must be even smaller than the width of the ridge part. However, when the contact hole is narrow, contact resistance between the contact layer in the upper part of the ridge part and the electrode increases, causing device characteristics to deteriorate. Because of this, it is not possible to obtain suitable device characteristics when the upper surface of the ridge part is narrow.

Moreover, accurate alignment is necessary to form the contact hole which is even narrower than the ridge part, and thereby achieve a contact hole which is entirely within the ridge part.

Also, the Ti film used in the lowest layer of the electrode is generally a metal film of the type used in a P-type electrode for contacting the P-type contact layer. The Ti film cannot therefore be used in the lowest layer of an electrode that contacts a different type of contact layer such as an N-type contact layer.

### SUMMARY

According to one aspect of an embodiment, a photonic semiconductor device includes: a semiconductor layer having a ridge-form protruding part and formed on a semiconductor substrate; a resin layer formed on surface parts on both sides of the protruding part so that the protruding part is embedded; a first insulating film including an opening that is formed on the resin layer and exposes an upper surface of the protruding part and a portion of a upper surface of the resin layer on both sides of the protruding part; a first electrode formed in the opening so as to cover the upper surface of the protruding part, and electrically coupled to an upper part of the protruding part; and a second electrode, electrically coupled to the first electrode, formed on the first electrode and the first insulation film.

According to another aspect of an embodiment, a manufacturing method for a photonic semiconductor device includes steps of forming, on a semiconductor substrate, a semiconductor layer having a ridge-form protruding part; forming a resin layer on the semiconductor layer; exposing an upper surface of the protruding part by etching the resin layer; forming a first insulation film on the protruding part and the resin layer; removing the first insulation film from an upper surface of the protruding part and from a portion of the resin layer on both sides of the protruding part; forming a first electrode, which electrically couples to an upper part of the protruding part, on the protruding part and on portions of the resin layer on both sides of the protruding part, so as to cover the upper surface of the protruding part; and forming a second electrode on the first electrode and the first insulation film, and electrically coupled to the first electrode.

According to a further aspect of an embodiment, a manufacturing method for a photonic semiconductor device includes steps of a manufacturing method for a photonic semiconductor device, comprising steps of: forming on a semiconductor substrate a semiconductor layer having a ridge-form protruding part; forming a resin layer on the semiconductor layer; forming a first insulation film on the resin layer; forming, in the first insulation film and the resin layer, an opening that reaches the protruding part and a portion of the resin layer on both sides of the protruding part; forming, in the opening, so as to cover an upper surface of the protruding part, a first electrode electrically coupled to an upper part of the protruding part; and forming, on the first electrode and the first insulation film, a second electrode that is electrically coupled to the first electrode.

### BRIEF DESCRIPTION OF THE DRAWINGS

FIG. 1 shows a conventional structure of a ridge-type photonic semiconductor device;

FIG. 2 shows a structure of a photonic semiconductor device according to a first embodiment of the present invention;

FIGS. 3A-3I show a process of manufacturing for a photonic semiconductor device according to a first embodiment of the present invention;

FIG. 4 shows a structure of a photonic semiconductor device according to a second embodiment of the present invention;

FIGS. 5A-5F show a process of manufacturing a photonic semiconductor device according to a second embodiment of the present invention;

FIG. 6 shows a structure of a photonic semiconductor device according to a third embodiment of the present invention;

FIGS. 7A-7E show a process of manufacturing a photonic semiconductor device according to a third embodiment of the present invention;

FIG. 8 shows a structure of a photonic semiconductor device according to a forth embodiment of the present invention; and

FIG. 9 shows a structure of a photonic semiconductor device.

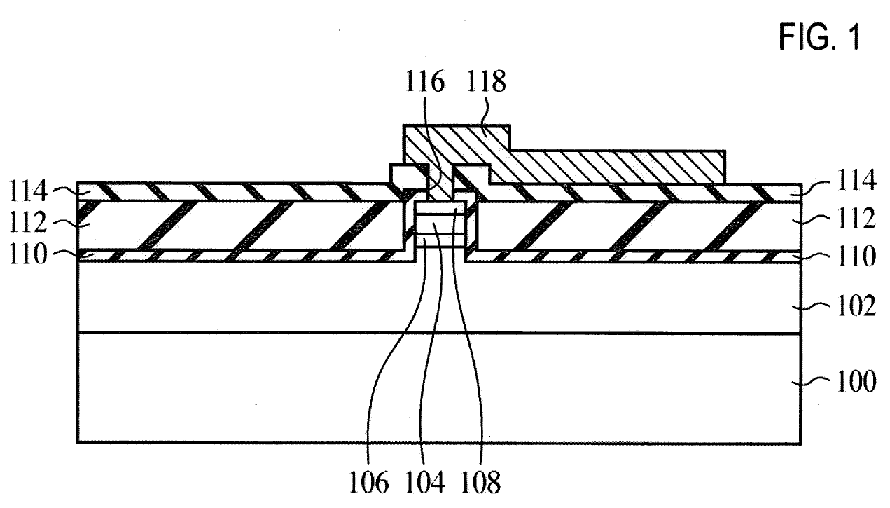

### DESCRIPTION OF THE PREFERRED EMBODIMENTS

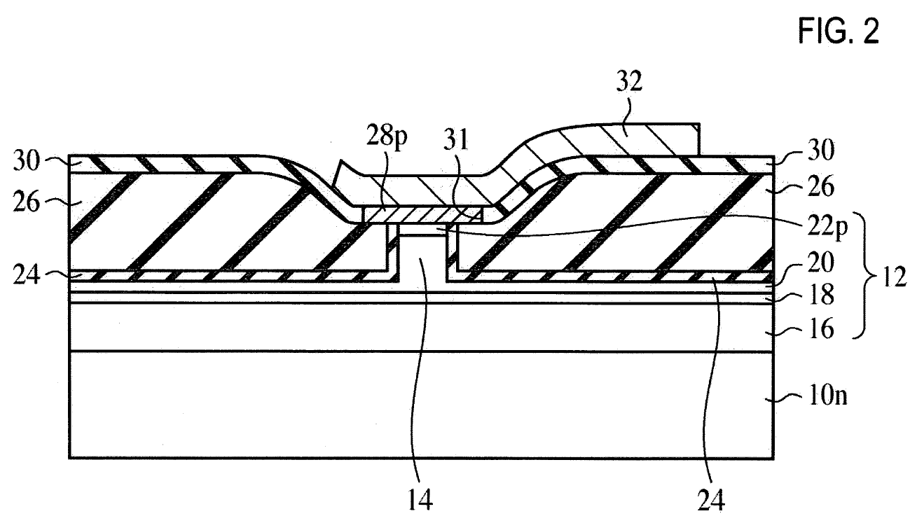

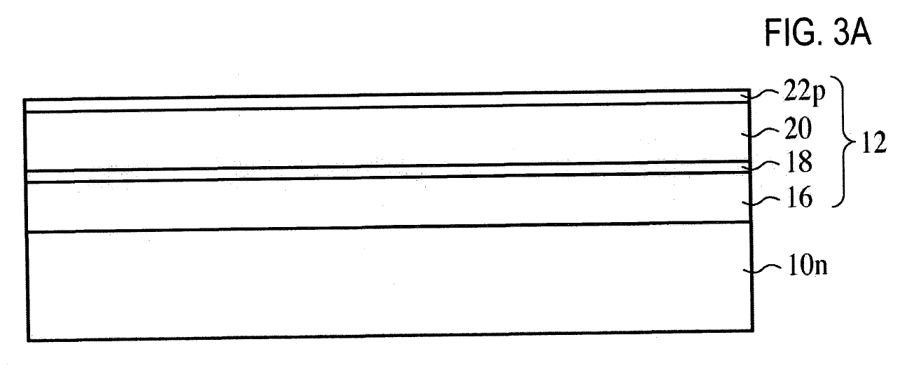

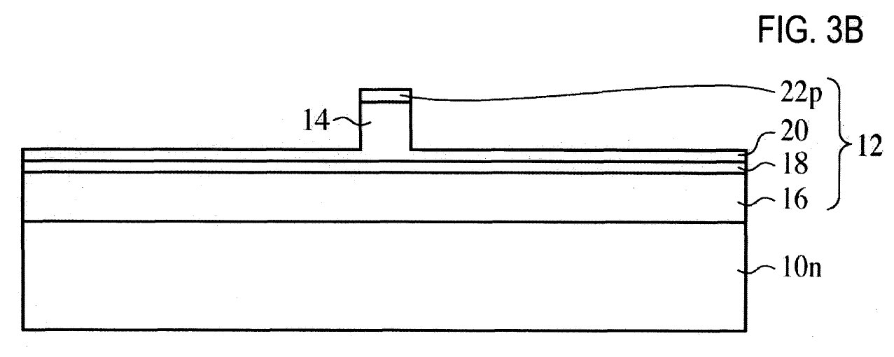

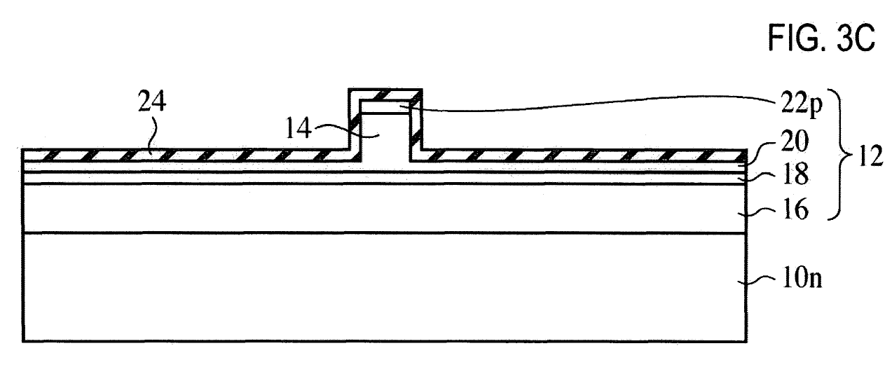

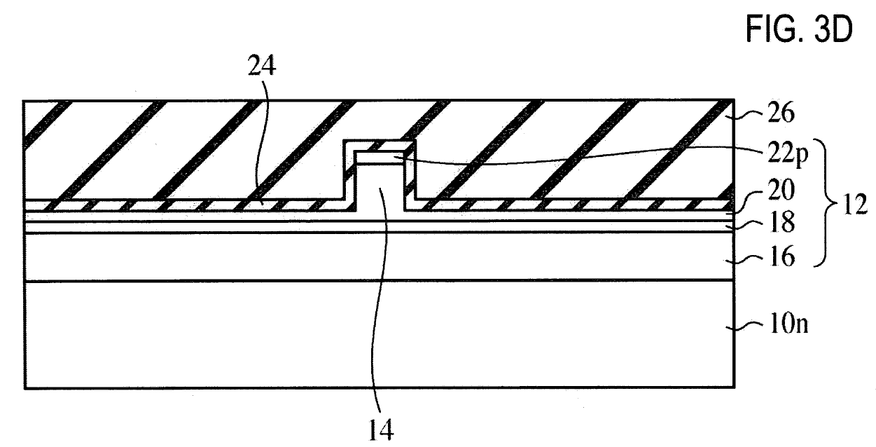

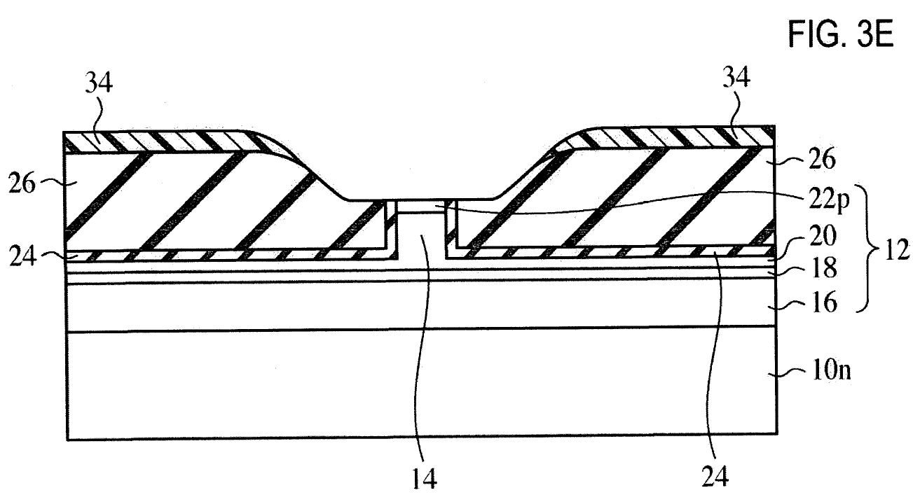

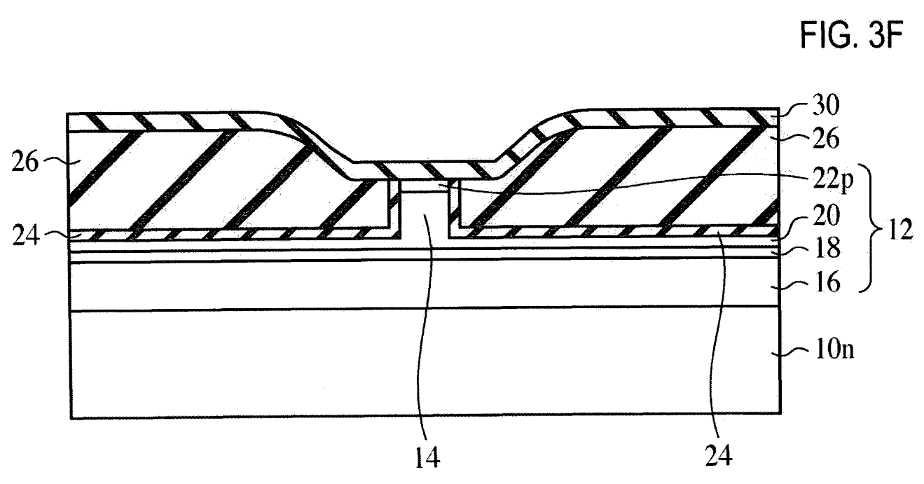

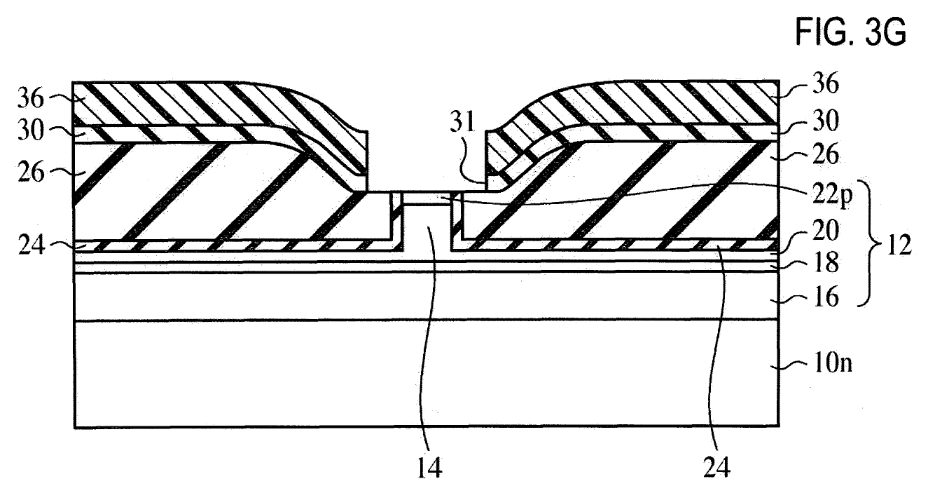

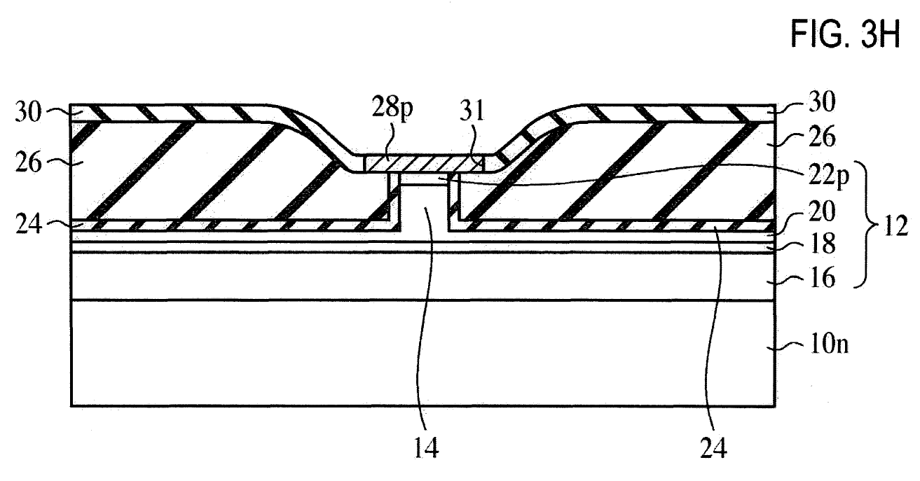

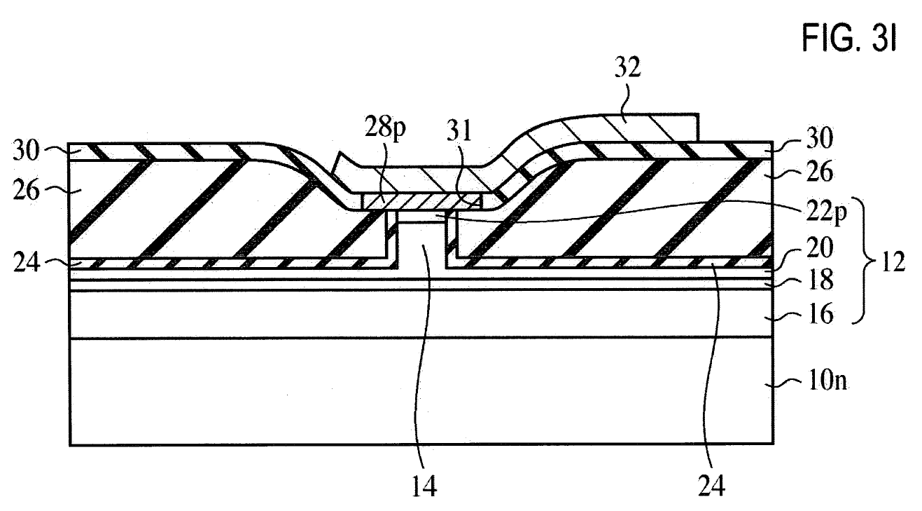

FIGS. 2 and 3A through 3I show a first embodiment of the present invention. The photonic semiconductor device of FIG. 2 is a ridge-type semiconductor laser including a semiconductor layer that has been processed to form a ridge. A semiconductor layer 12 which has been ridge-form processed and has a protruding ridge part 14 is formed on an N-type semiconductor substrate 10n.

The semiconductor layer 12 includes a lower cladding layer 16 on the N-type semiconductor substrate 10n, an active layer 18 formed on the lower cladding layer 16, an upper cladding layer 20 formed on the active layer 18, and a P-type contact layer 22p formed on the upper cladding layer 20. The upper parts of the P-type contact layer 22p and the upper cladding layer 20 are ridge-form processed to form the ridge part 14.

An insulation film 24 made up of silicon oxide film is formed on side surfaces of the ridge part 14 and on the semiconductor layer 12 on both sides of the ridge part 14. The insulation film 24 functions as a passivation film. An upper surface height of the insulation film 24 formed on the sides of the ridge part 14 is approximately the same as an upper surface height of the P-type contact layer 22p.

A resin layer 26 made up of BCB resin is formed on the semiconductor layer 12 on both sides of the ridge part 14 where the insulation film 24 is formed. Thus, the resin layer 26 is formed on surfaces on both sides of the ridge part 14 so that the ridge part 14 is embedded. The upper surface height of the resin layer 26 is approximately the same as the upper surface height of the P-type contact layer 22p in regions near the ridge part 14. In other regions, the upper surface height of the resin layer 26 is approximately the same as or higher than the upper surface height of the P-type contact layer 22p.

A P-type electrode 28p that electrically couples to the P-type contact layer 22p is formed along the width direction of the ridge part 14 so as to cover the upper surfaces of the P-type contact layer 22p of the ridge part 14 and the insulation film 24 and resin layer 26 on both sides of the ridge part 14. The P-type electrode 28p is constructed using Au/Zn/Au layered film made up of sequentially layered Au film, Zn film, and Au film. The lower layer of the P-type electrode 28p is alloyed with the upper layer of the P-type contact layer 22p. Note that a Pt/Ti layered film made up of sequentially layered Ti film and Pt film may be used as the P-type electrode 28.

An insulation film 30 made up of silicon nitride film is formed on regions of the resin layer 26 where the P-type electrode 28p is not formed. In other words, an opening 31 which exposes the upper surface of the ridge part 14, the upper surface of insulation film 24 on both side surfaces of the ridge part 14, and the upper surface of the resin layer 26 is formed in the insulation film 30, and the P-type electrode 28p is formed in the opening 31. For the insulation film 30, a silicon nitride film with different etching characteristics to the silicon oxide film of the insulation film 24 is used. Note, however, that insulation films 24 and 30 are not limited to silicon oxide and silicon nitride films. Any insulation films with differing etching characteristics can be used as the insulating films 24 and 30. To be more specific, the etching rate of the insulation film 30 for the etching liquid used in etching of the insulation film 30 may be faster than the etching rate of the insulation film 24, and materials for the insulation films 24 and 30 can be selected appropriately. Alternatively, insulation films for which the etching characteristics are similar and for which the etching rates for the etching liquid used to etch the insulation film 30 are similar may be used as the insulation films 24 and 30. For instance, silicon oxide film may be used for both the insulation film 24 and the insulation film 30. Also, silicon nitride film may be used for both the insulation film 24 and the insulation film 30. Note, the etching rates for the insulation films 24 and 25 are described later.

A pad electrode 32 electrically coupled to the P-type electrode 28p is formed on the P-type electrode 28p and the insulation film 30 so as to cover the P-type electrode 28p. The pad electrode 32 is constructed from an Au/Pt/Ti layered film made up of sequentially layered Ti film, Pt film and Au film, and has a metal composition that differs from the metal composition of the P-type electrode 28p. Thus, a Ti film which has a favorable adhesiveness with respect to the contacting insulation film 30 is used in the lowest layer of the pad electrode 32. An Au film of the same Au used as a wiring metal when building devices is used in the uppermost layer of the pad electrode 32. Note that the lowest layer of the pad electrode 32 is not limited to a Ti film. Other films capable of adhering favorably to the insulation film 30, such as a TiW film, a Ni film, or a Cr film, may be used. An Au/TiW layered film made up of sequentially layered TiW film and Au film may be used as the pad electrode 32. When Al is used as the wiring metal for building the device, Al is used in the uppermost layer of the pad electrode 32.

The photonic semiconductor device of the present embodiment is constructed as described. The photonic semiconductor device of the present embodiment is characterized by the inclusion of the P-type electrode 28p formed along the width direction of the P-type contact layer 22p so as to cover the upper surface of the P-type contact layer 22p, and the pad electrode 32 formed to cover the P-type electrode 28p.

In the photonic semiconductor device of the present embodiment, rather than the electrode being coupled via the contact hole that passes through the upper surface of P-type contact layer 22p, a P-type electrode 28p is formed along the width direction of the P-type contact layer 22p so as to cover the upper surface of the P-type contact layer 22p. Hence, the increase in contact resistance caused by the miniaturization of the contact hole is avoided, and it is possible to sufficiently reduce the contact resistance between the P-type contact layer 22p and the P-type electrode 28p. For instance, in the case that the characteristic contact resistance of the P-type electrode 28p is 2×10-6 Ωcm², the resonant wavelength of the device is 500 μm, and the width of the ridge part 14 is 3 μm, the contact resistance is 0.13Ω because the present embodiment allows the P-type electrode 28p to be formed over the entire upper surface of the ridge part 14.

Contrastingly, in the case that a contact hole which is entirely within the ridge part 14 is formed, the contact hole would have a width of approximately 1 μm. In this case, the calculated contact resistance is approximately 0.4Ω, at least three times the resistance in the present embodiment.

Moreover, in the photonic semiconductor device of the present embodiment, the P-type electrode 28p and the pad electrode 32 are formed independently of each other. This means that the electric materials for the P-type electrode 28p and the pad electrode 32 can be chosen with a high level of freedom. The electrical material of the P-type electrode 28p can be selected depending on the conductive type of the P-type contact layer 22p. Also, the electrical material of the pad electrode 32 can be selected based on consideration of adhesiveness with respect to the substrate insulation film 30 and the type of wiring metal used when building the device.

Moreover, since a pad electrode 32 is formed so as to cover the P-type electrode 28p, it is possible to suppress the occurrence of electrode peeling. The following describes the manufacturing method of the photonic semiconductor device according to the present embodiment with reference to FIGS. 3A through 3I.

First, the semiconductor layer 12, having the lower cladding layer 16, the active layer 18, the upper cladding layer 20, and the P-type contact layer 22p sequentially layered, is formed on the N-type semiconductor substrate 10 (FIG. 3A). Next, using, for example, dry etching, the P-type contact layer 22p and the upper cladding layer 20 of the semiconductor layer 12 are processed to ridge form, thereby forming the ridge part 14 (FIG. 3B). Subsequently, the insulation film 24 composed, for instance, of silicon oxide film at a thickness of 400 nm is formed over the entire surface using a method such as CVD (FIG. 3C).

Afterward, a BCB resin, which is a resin with a high molecular weight, is applied to the entire surface and hardened. The resin layer 26 made up of the BCB resin at a thickness of, for instance, 2 μm is thereby formed (FIG. 3D). Note that the application and hardening of the BCB resin is performed in way that gives an approximately flat surface in the formed resin layer 26.

In the next step, a region along the ridge part 14 and wider than the width of the ridge part 14 on resin layer 26 is exposed using photolithography, and a photoresist film 34 covering the other regions is formed. With the photoresist film 34 as a mask, the resin layer 26 and the insulation film 24 are sequentially etched. This exposes the upper surface of the P-type contact layer 22p of the upper part of the ridge part 14 (FIG. 3E). After the upper surface of the P-type contact layer 22p has been exposed, the photoresist film 34 that was used as a mask is removed.

Following the mask removal, the insulation film 30 composed, for instance, of silicon nitride at a thickness of 300 nm is formed over the entire surface using a method such as plasma CVD (FIG. 3F). Next, using photolithography on the insulation film 30, a region for forming the P-type electrode 28p is exposed and a photoresist film 36 covering the other regions is formed. With the photoresist film 36 as a mask, the insulation film 30 is etched. This forms the opening 31 in the insulation film 30, and exposes the upper surface of the P-type contact layer 22p, the upper surface of the insulation film 24 and the upper surface of the resin layer 26 in the region for forming the P-type electrode 28p (FIG. 3G). As described above, an insulation film with etching characteristics which differ from those of the insulation film 24 is used for the insulation film 30. Specifically, an insulation film having an etching rate that is higher, for the etching liquid used to etch the insulation film 30, than the etching rate of the insulation film 24 is used. By using insulation films 24 and 30 with these etching characteristics, excessive removal by etching of the insulation film 24 on the side surfaces of the ridge part 14 can be prevented. Note that insulation films for which the etching characteristics are similar and for which the etching rates for the etching liquid used to etch the insulation film 30 are similar may be used as the insulation films 24 and 30.

With the photoresist film 36 left in place, an Au film at a thickness of 200 nm, a Zn film or the like at thickness of 20 nm, and an Au film or the like at a thickness of 20 nm are sequentially layered over the entire surface. The Au/Zn/Au layered film on the photoresist film 36 is then removed together with the photoresist film 36. Thus, the P-type electrode 28p made up of the Au/Zn/Au layered film is formed using a lift-off method (FIG. 3H).

Next, the lower layer of the P-type electrode 28p is alloyed with the upper layer of the P-type contact layer 22p by performing heat treatment. Using photolithography on the insulation film 30, a region for forming the pad electrode 32 which includes the region of the P-type electrode 28p is exposed, and a photoresist film (not shown in the drawings) covering the other regions is formed. A Ti film at a thickness of 100 nm or the like, a Pt film at a thickness of 200 nm or the like, and an Au film at a thickness of 1 μm or the like are sequentially layered over the entire surface using a method such as a vapor deposition or sputtering. The Au/Pt/Ti layered film on the photoresist film is then removed together with the photoresist film. Thus, the pad electrode 32 made up of the Au/Pt/Ti layered film is formed using a lift-off method (FIG. 3I).

The photonic semiconductor device of the present embodiment shown in FIG. 2 is manufactured as described above. Hence, since the P-type electrode 28p is formed along the width direction of the P-type contact layer 22p so as to cover the upper surface of the P-type contact layer 22p, the contact resistance between the P-type contact layer 22p and the P-type electrode 28p can be reduced.

Moreover, since the P-type electrode 28p and the pad electrode 32 are formed independently of each other, the electrical materials of the P-type electrode 28p and the pad electrode 32 can be chosen with great freedom. Further, since the pad electrode 32 is formed so as to cover the P-type electrode 28p, it is possible to suppress the occurrence of electrode peeling.

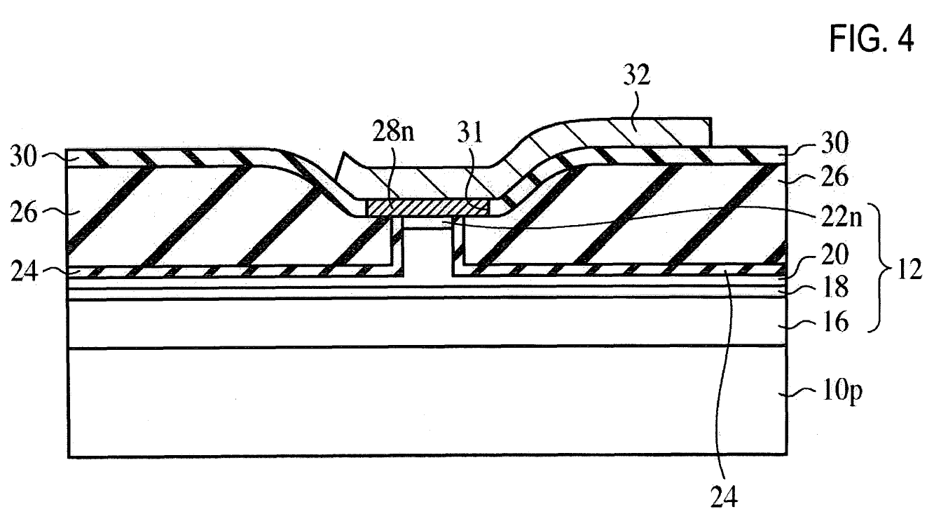

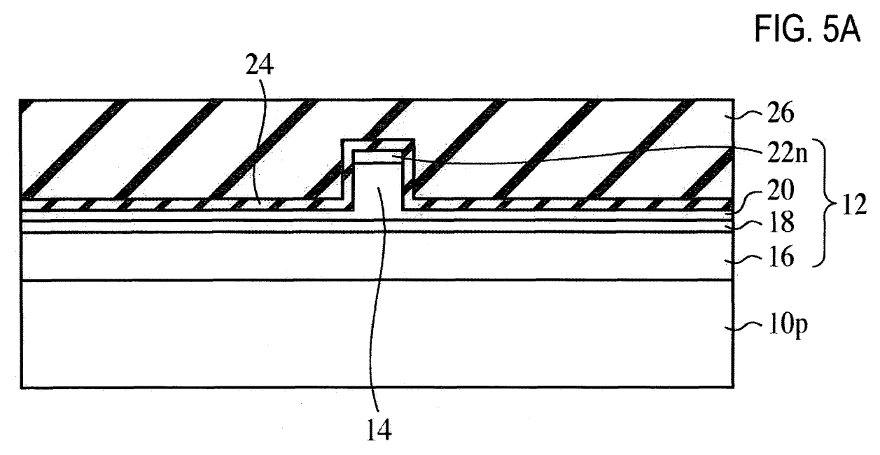

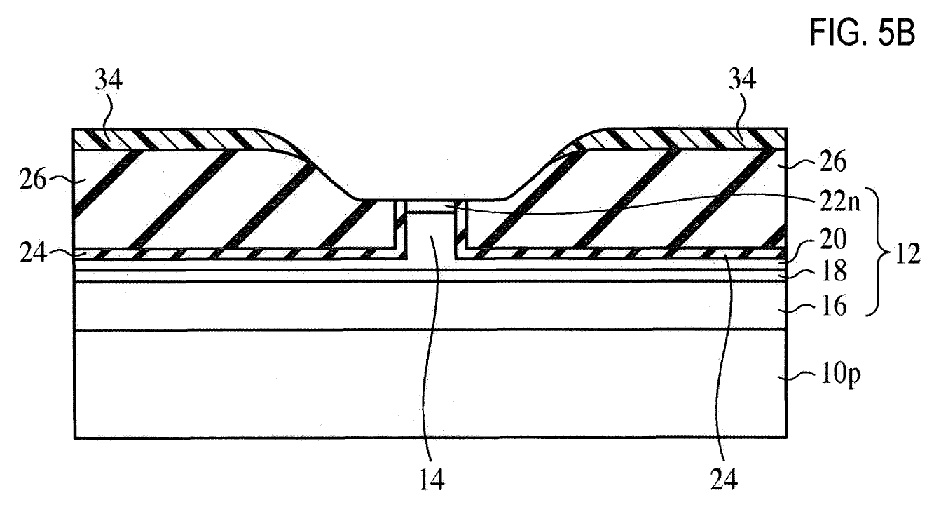

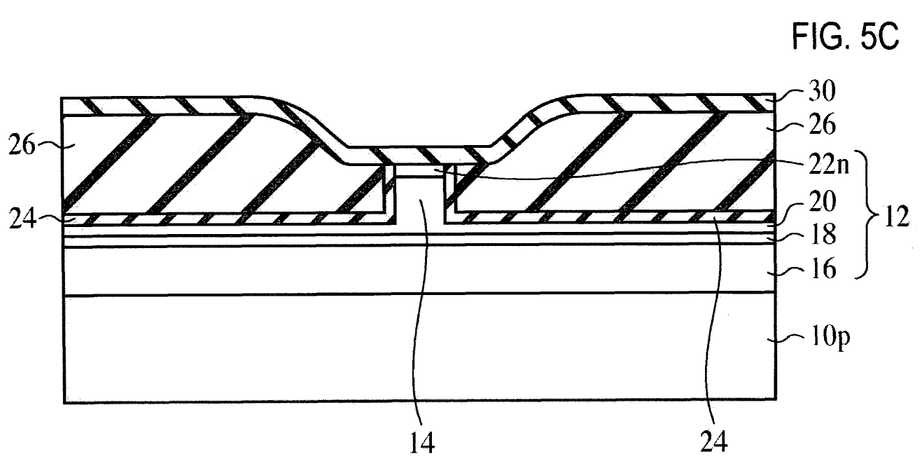

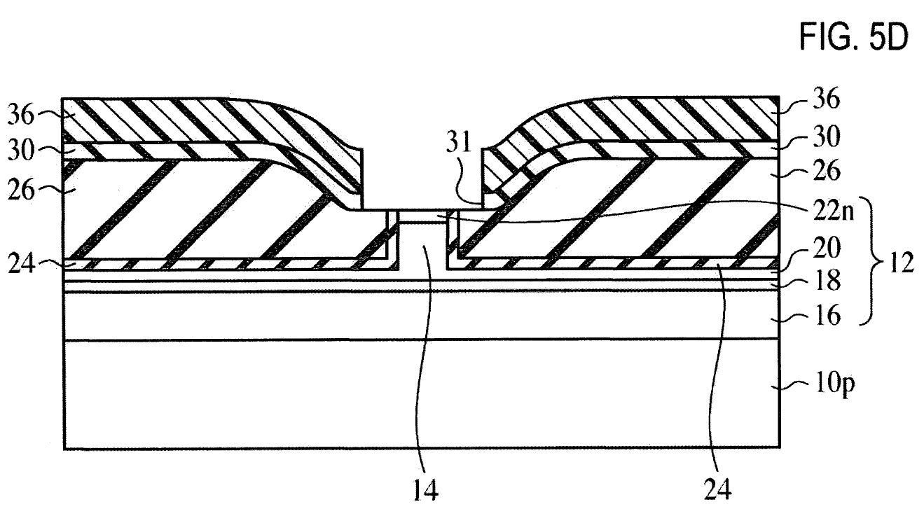

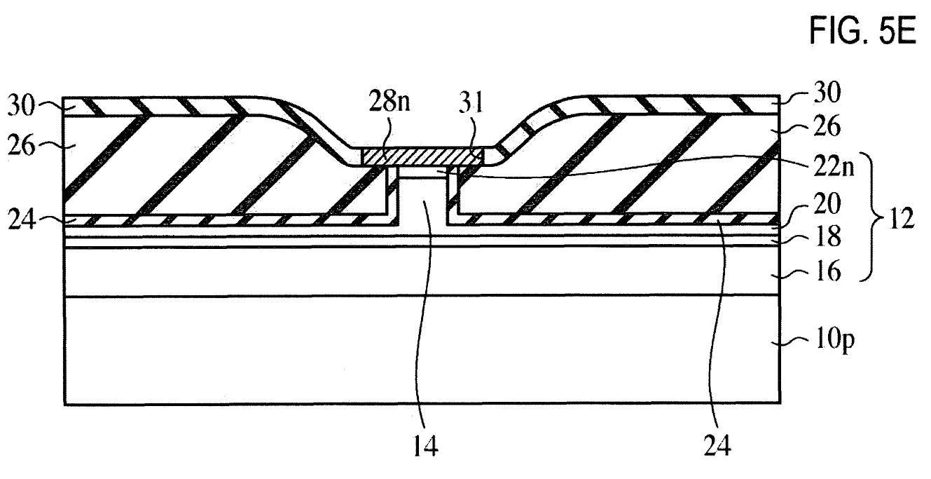

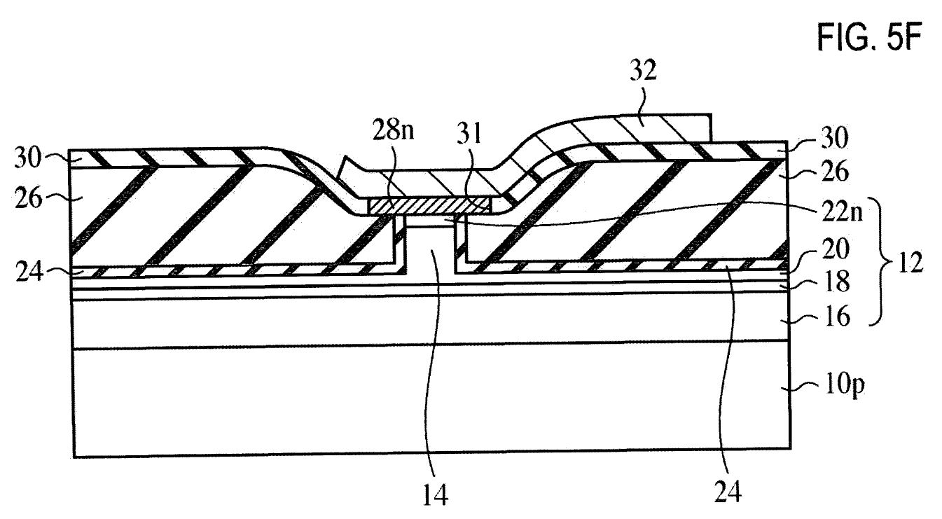

FIGS. 4 and 5A through 5F show a second embodiment. Note that elements of the photonic semiconductor device and manufacturing method which are the same as those of the first embodiment have the same symbols. Moreover, description of these elements are omitted or simplified.

First, the construction of the photonic semiconductor device according to the present embodiment is described with reference to FIG. 4. The basic construction of the photonic semiconductor device of the present embodiment is substantially the same as the construction of the photonic semiconductor device of the first embodiment. The photonic semiconductor device according to the present embodiment differs from the photonic semiconductor device of the first embodiment in that a P-type semiconductor substrate 10p is used in place of the N-type semiconductor substrate and further in the construction of the upper part of the contact layer of the ridge part 14 and electrode coupling to the contact layer.

As shown in the drawings, a semiconductor layer 12, which has been ridge-form processed and has a protruding ridge part 14, is formed on a P-type semiconductor substrate 10p. The semiconductor layer 12 includes a lower cladding layer 16 formed on the P-type semiconductor substrate 10p, an active layer 18 formed on the lower cladding layer 16, an upper cladding layer 20 formed on the active layer 18, and an N-type contact layer 22n formed on the upper cladding layer 20. The upper parts of the N-type contact layer 22n and the upper cladding layer 20 are ridge-form processed to form the ridge part 14.

An insulation film 24 made up of silicon oxide film and a resin layer 26 made up of BCB resin are formed on the semiconductor layer 12 on which the ridge part 14 is formed in the same way as in the photonic semiconductor device of the first embodiment.

An N-type electrode 28n that electrically couples to the N-type contact layer 22n is formed along the width direction of the ridge part 14 so as to cover the upper surfaces of the N-type contact layer 22n of the ridge part 14 and the insulation film 24 and resin layer 26 on both sides of the ridge part 14. The N-type electrode 28n is constructed using Au/AuGe layered film made up of sequentially layered AuGe film and Au film. The lower layer of the N-type electrode 28n is alloyed with the upper layer of the N-type contact layer 22n. Note, the N-type electrode 28n may be constructed using Au/Ni/AuGe layered film made up of sequentially layered AuGe film, Ni film and Au film.

An insulation film 30 made up of silicon nitride film is formed on regions of the resin layer 26 where the N-type electrode 28n is not formed. In other words, an opening 31 which exposes the upper surface of the ridge part 14, the upper surface of insulation film 24 on both side surfaces of the ridge part 14, and the upper surface of the resin layer 26 is formed in the insulation film 30, and the N-type electrode 28n is formed in the opening 31.

A pad electrode 32 that electrically couples to the N-type electrode 28n is formed on the N-type electrode 28n and the insulation film 30 so as to cover the N-type electrode 28n. The pad electrode 32 is constructed from an Au/Pt/Ti layered film made up of sequentially layered Ti film, Pt film and Au film, and has a metal composition that differs from the metal composition of the N-type electrode 28n.

The photonic semiconductor device of the present embodiment is constructed as described. The photonic semiconductor device of the present embodiment is characterized by the inclusion of the N-type electrode 28n formed along the width direction of the N-type contact layer 22n so as to cover the upper surface of the N-type contact layer 22n, and the pad electrode 32 formed to cover the N-type electrode 28n.

Since, in the photonic semiconductor device of the present embodiment, the N-type electrode 28n is formed along the width direction of the N-type contact layer 22n so as to cover the upper surface of the N-type contact layer 22n in the same way as the P-type electrode 28p in the photonic semiconductor device of the first embodiment, the increase in contact resistance caused by the miniaturization of the contact hole is avoided, and it is possible to sufficiently reduce the contact resistance between the N-type contact layer 22n and the N-type electrode 28n.

Moreover, in the photonic semiconductor device of the present embodiment, the N-type electrode 28n and the pad electrode 32 are formed independently of each other. This means that the electric materials for the N-type electrode 28n and the pad electrode 32 can be chosen with a high degree of freedom. The electrical material of the N-type electrode 28n can be selected depending on the conductive type of the N-type contact layer 22n. Also, the electrical material of the pad electrode 32 can be selected based on consideration of adhesiveness with respect to the substrate insulation film 30 and the type of wiring metal used when building the device. Moreover, since the pad electrode 32 is formed so as to cover the N-type electrode 28n, it is possible to suppress the occurrence of electrode peeling.

The following describes the manufacturing method of the photonic semiconductor device according to the present embodiment with reference to FIGS. 5A through 5F.

First, the processes up to the formation of the resin layer 26 (FIG. 5A) are performed. Except in the use of the P-type semiconductor substrate 10p in place of the N-type semiconductor substrate 10n and in the formation of the N-type contact layer 22n as the contact layer of the upper part of the ridge part 14, the manufacturing method up to this point is the same as for the photonic semiconductor device of the first embodiment shown in FIGS. 3A through 3D.

Next, using photolithography on the resin layer 26, a region along the ridge part 14 and wider than the width of the ridge part 14 is exposed and the photoresist film 34 covering the other regions is formed. With the photoresist film 34 as a mask, the resin layer 26 and the insulation film 24 are sequentially etched. This exposes the upper surface of the N-type contact layer 22n of the upper part of the ridge part 14 (FIG. 5B). After the upper surface of the N-type contact layer 22n has been exposed, the photoresist film 34 that was used as a mask is removed.

Following the removal of the mask, the insulation film 30 made up of, for instance, a silicon nitride film at a thickness of 300 nm is formed over the entire surface using a method such as plasma CVD (FIG. 5C). Next, using photolithography on the insulation film 30, a region for forming the N-type electrode 28n is exposed and a photoresist film 36 covering the other regions is formed. With the photoresist film 36 as a mask, the insulation film 30 is etched. This forms the opening 31 in the insulation film 30, and exposes the upper surface of the N-type contact layer 22n, the upper surface of the insulation film 24 and the upper surface of the resin layer 26 in the region for forming the N-type electrode 28n (FIG. 5D).

With the photoresist film 36 left in place, an AuGe film at a thickness of 200 nm and an Au film at a thickness of 50 nm or the like are sequentially layered over the entire surface. The Au/AuGe layered film on the photoresist film 36 is then removed together with the photoresist film 36. Thus, the N-type electrode 28n made up of the Au/AuGe layered film is formed using a lift-off method (FIG. 5E).

Next, the lower layer of the N-type electrode 28n is alloyed with the upper layer of the N-type contact layer 22n by performing heat treatment. Thereafter, the pad electrode 32 made up of the Au/Pt/Ti layered film is formed using a lift-off method (FIG. 5F) in the same way as in the manufacturing method for the photonic semiconductor device of the first embodiment.

The photonic semiconductor device of the present embodiment shown in FIG. 4 is manufactured in this way. Thus, since the N-type electrode 28n is formed along the width direction of the N-type contact layer 22n so as to cover the upper surface of the N-type contact layer 22n, the contact resistance between the N-type contact layer 22n and the N-type electrode 28n can be reduced.

Moreover, since the N-type electrode 28n and the pad electrode 32 are formed independently of each other, the electrical materials of the N-type electrode 28n and the pad electrode 32 can be chosen with a high degree of freedom. Further, since the pad electrode 32 is formed so as to cover the N-type electrode 28n, it is possible to suppress the occurrence of electrode peeling.

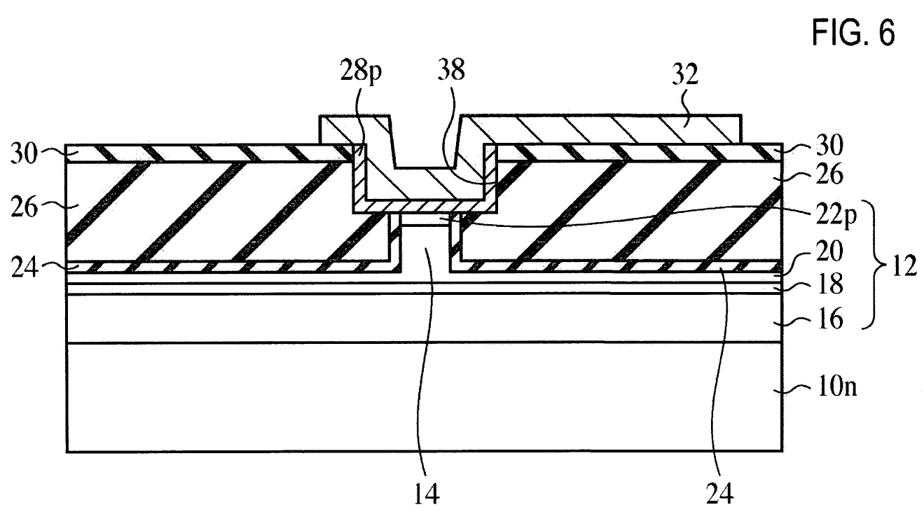

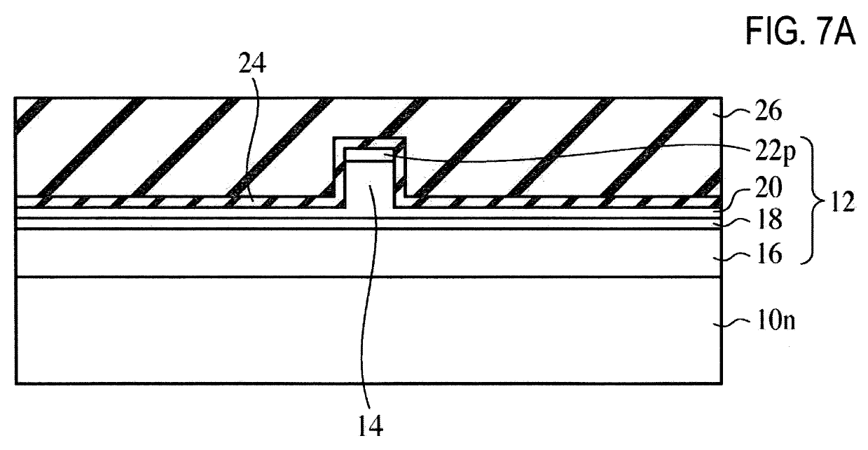

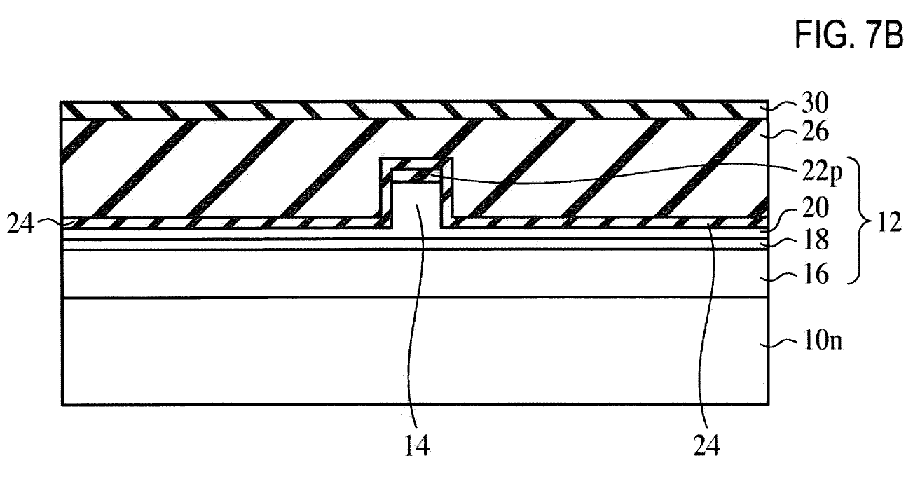

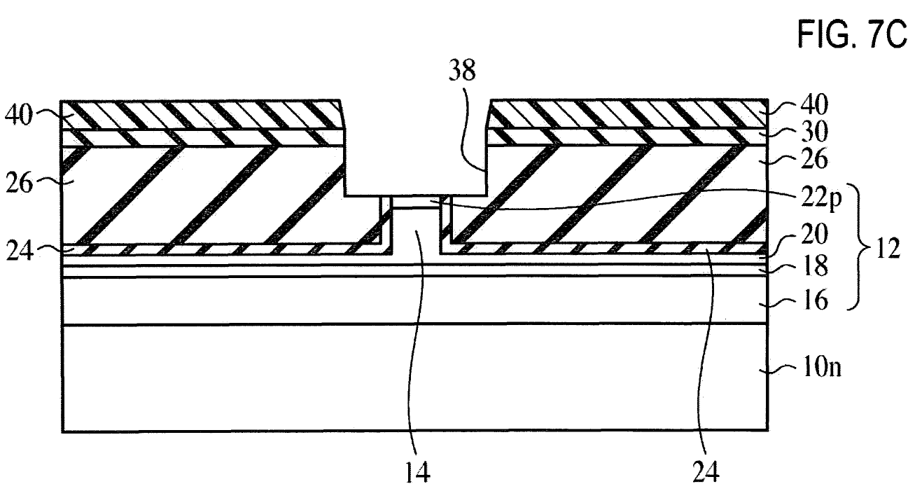

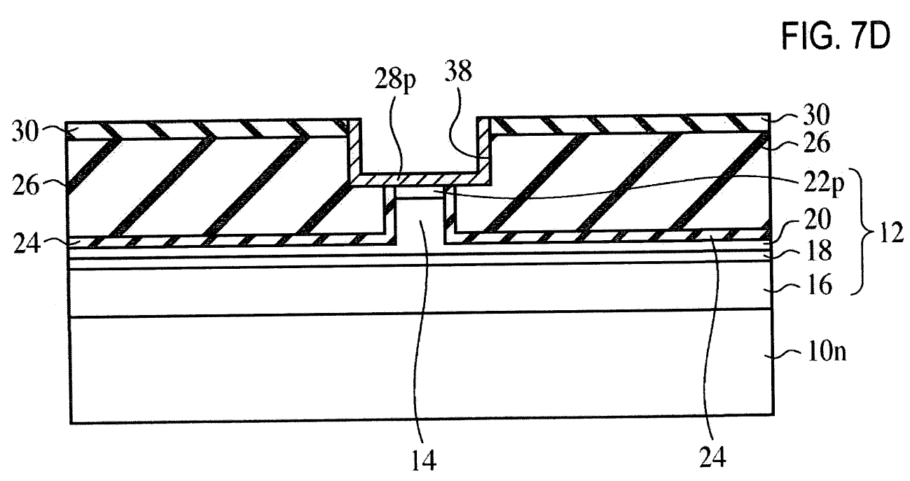

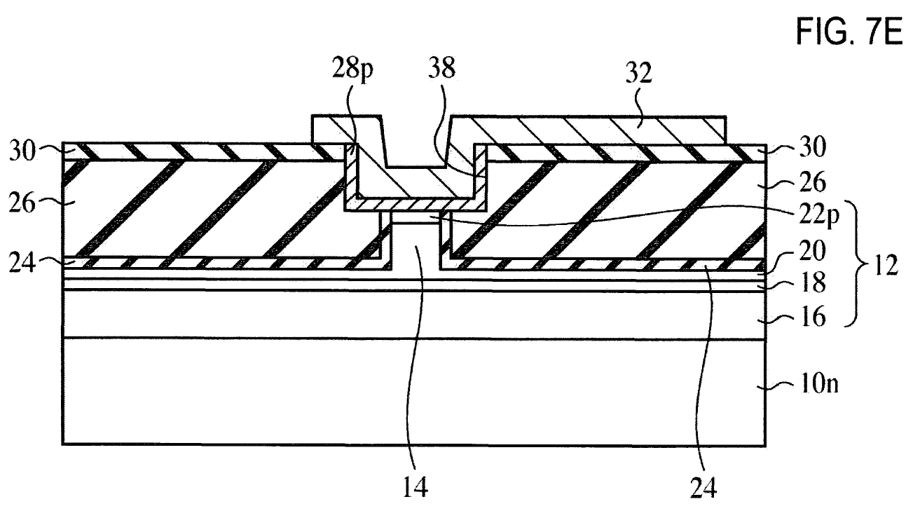

FIGS. 6 and 7A through 7E show a third embodiment. Note that elements of the photonic semiconductor device and manufacturing method which are the same as those of the first embodiment have the same symbols. Moreover, descriptions of these elements are omitted or simplified.

First, the construction of the photonic semiconductor device of the present embodiment is described with reference to FIG. 6. The basic construction of the photonic semiconductor device of the present embodiment is substantially the same as the construction of the photonic semiconductor device of the first embodiment. The photonic semiconductor device of the present embodiment differs from the photonic semiconductor device of the first embodiment in that the P-type electrode 28p is coupled to the P-type contact layer 22p via an opening 38 formed in the insulation film 30 and the resin layer 26.

As shown in the drawings, the semiconductor layer 12 which has the ridge part 14 is formed on the N-type semiconductor substrate 10n in the same way as in the photonic semiconductor device of the first embodiment. An insulation film 24 made up of silicon oxide film is formed on the semiconductor layer 12 on which the ridge part 14 is formed. A resin layer 26 made up of BCB is formed on the insulation film 24. An insulation film 30 made up of silicon nitride film is formed on the resin layer 26.

The opening 38 is formed in the insulation film 30, the resin layer 26, and the insulation film 24 along the length direction of the ridge part 14. At the bottom surface of the opening 38, the upper surface of the P-type contact layer 22p, the upper surface of the insulation film 24 on both sides of the ridge part 14, and the upper surface of the resin layer 26 are exposed.

The P-type electrode 28p that is electrically coupled to the P-type contact layer 22p is formed on the bottom and side surfaces of the opening 38. The P-type electrode 22p is formed along the width direction of the ridge part 14 so as to cover the upper surface of the P-type contact layer 22p exposed at the bottom surface of the opening 38, and the upper surfaces of the insulation film 24 and the resin layer 26 on both sides of the ridge part 14.

A pad electrode 32 electrically coupled to the P-type electrode 28p is formed on the P-type electrode 28p and the insulation film 30 so as to cover the P-type electrode 28p formed in the opening 38.

The photonic semiconductor device of the present embodiment is constructed as described above. As in the photonic semiconductor device of the present embodiment, the P-type electrode 28p may be formed along the width direction of the P-type contact layer 22p so as to cover the upper surface of the P-type contact layer 22p via the opening 38 formed in the insulation film 30, the resin layer 26 and the insulation film 24. The photonic semiconductor device according to the present embodiment having the above-described structure can be manufactured using fewer processes than the photonic semiconductor device according to the first embodiment.

The following describes the manufacturing method of the photonic semiconductor device according to the present embodiment with reference to FIGS. 7A through 7E.

First, the resin layer 26 is formed (FIG. 7A) in the same way as in the manufacturing method, shown in FIGS. 3A through 3D, for the photonic semiconductor device of the first embodiment. Next, the insulation film 30 made up of, for instance, a silicon nitride film at a thickness of 300 nm is formed on the resin layer 26 using a method such as plasma CVD (FIG. 7B). Using photolithography on the insulation film 30, a region for forming the opening 38 is exposed and a photoresist film 40 covering the other regions is formed. With the photoresist film 40 as a mask, the insulation film 30, the resin layer 26 and the insulation film 24 are sequentially etched. By this etching, the opening 38 with the bottom surface that exposes the upper surface of the P-type contact layer 22p, the upper surface of the insulation film 24 on both sides of the ridge part 14, and the upper surface of the resin layer 26 is formed in the length-wise direction of ridge part 14 (FIG. 7C).

Next, with the photoresist film 40 left in place, an Au film at a thickness of 200 nm, a Zn film at thickness of 20 nm or the like, and a Au film at a thickness of 20 nm or the like are sequentially layered over the entire surface by a method such as vapor deposition. The Au/Zn/Au layered film on the photoresist film 40 is then removed together with the photoresist film 40. Thus, the P-type electrode 28p made up of the Au/Zn/Au layered film is formed using a lift-off method (FIG. 7D). Subsequently, the lower layer of the P-type electrode 28p is alloyed with the upper layer of the P-type contact layer 22p by performing heat treatment.

After the above, using photolithography on the insulation film 30, a region for forming the pad electrode 32 which includes the P-type electrode 28p formed in the opening 38 is exposed, and a photoresist film (not shown in the drawings) covering the other regions is formed. Next, a Ti film at a thickness of 100 nm or the like, a Pt film at a thickness of 200 nm or the like, and an Au film at a thickness of 1 μm or the like are sequentially layered over the entire surface using a method such as a vapor deposition or sputtering. Thereafter, the Au/Pt/Ti layered film on the photoresist film is then removed together with the photoresist film. Thus, the pad electrode 32 made up of the Au/Pt/Ti layered film is formed using a lift-off method (FIG. 7E).

The photonic semiconductor device according to the present embodiment shown in FIG. 6 is manufactured as described above. In the etching process, in which the photoresist film 40 is used as a mask, of the manufacturing method of the photonic semiconductor device according to the present embodiment, the insulation film 30, the resin layer 26, and the insulation film 24 are etched together, and so the number of processes is fewer than in the manufacturing method for the photonic semiconductor device according to the first embodiment.

Although in the above-described case the N-type semiconductor substrate 10n is used in the same way as in the photonic semiconductor device according to the first embodiment, the photonic semiconductor device can be constructed using the P-type semiconductor substrate 10p in the same way as in the photonic semiconductor device according to the second embodiment.

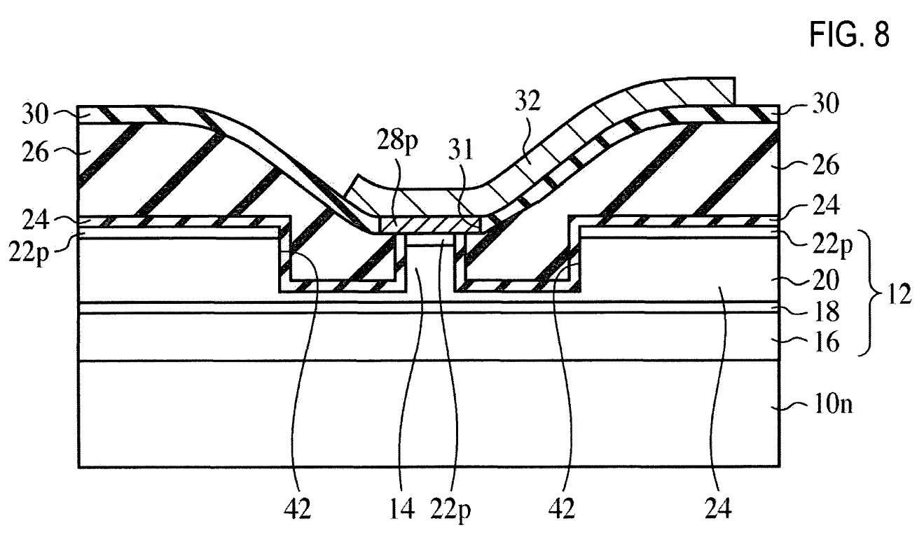

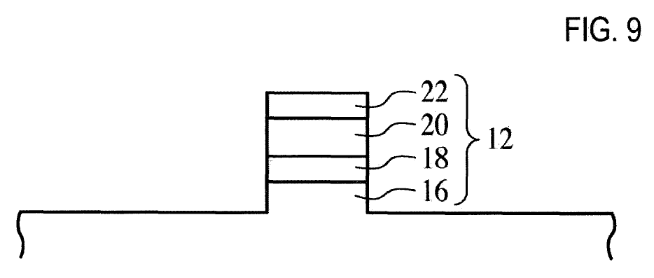

FIG. 8 shows the fourth embodiment. Note that elements of the photonic semiconductor device and manufacturing method which are the same as those of the first embodiment have the same symbols. Moreover, descriptions of these elements are omitted or simplified.

The basic construction of the photonic semiconductor device of the present embodiment is substantially the same as the construction of the photonic semiconductor device of the first embodiment. The photonic semiconductor device of the present embodiment differs from the photonic semiconductor device of the first embodiment in that the semiconductor layer 12 has a mesa-form protruding part. In other words, the photonic semiconductor device of the present embodiment has the ridge part 14 formed between a pair of groove parts 42 formed in parallel in the semiconductor layer 12.

As shown in the drawings, the semiconductor layer 12 is formed on the N-type semiconductor substrate 10n. The semiconductor layer 12 includes a lower cladding layer 16 formed on the N-type semiconductor substrate 10n, an active layer 18 formed on the lower cladding layer 16, an upper cladding layer 20 formed on the active layer 18, and a P-type contact layer 22p formed on the upper cladding layer 20.

The parallel pair of groove parts 42 is formed in the upper parts of the P-type contact layer 22p and the upper cladding layer 20 of the semiconductor layer 12. The protruding ridge part 14 is formed between the pair of groove parts 42. The insulation layer 24 made up of a silicon nitride film is formed on the side surfaces of the ridge part 14, the bottom and side surfaces of the groove parts 42, and the semiconductor layer 12 on both sides of the pair of groove parts 42. The upper surface height of the insulation film 24 formed on the sides of the ridge part 14 is approximately the same as the upper surface height of the P-type contact layer 22p.

The resin layer 26 made up of the BCB resin is in the pair of groove parts 42 formed by insulation film 24 and on the insulation film 24 of the semiconductor layer 12 on both sides of the pair of groove parts 42. Thus, the resin layer 26 is formed on surfaces to both sides of the ridge part 14 so that the ridge part 14 is embedded. The upper surface height of the resin layer 26 is approximately the same as the upper surface height of the P-type contact layer 22p in regions near the ridge part 14. In other regions, the upper surface height of the resin layer 26 is approximately the same as or higher than the upper surface height of the P-type contact layer 22p.

The P-type electrode 28p that electrically couples to the P-type contact layer 22p is formed along the width direction of the ridge part 14 so as to cover the upper surfaces of the P-type contact layer 22p of the ridge part 14 and the insulation film 24 and resin layer 26 on both sides of the ridge part 14. A pad electrode 32 electrically coupled to the P-type electrode 28p is formed on the P-type electrode 28p and the insulation film 30 so as to cover the P-type electrode 28p.

The photonic semiconductor device of the present embodiment is constructed as described above. The ridge part 14 may be formed between the pair of groove parts 42 formed in parallel in the semiconductor layer 12, as in the photonic semiconductor device of the present embodiment.

The photonic semiconductor device according to the present embodiment can be manufactured in the same way as the photonic semiconductor device of the first embodiment except in that the pair of groove parts 42 is formed on the semiconductor layer 12 using a method such as dry etching, and the ridge part 14 is formed between the two groove parts.

Although in the above-described case the N-type semiconductor substrate 10n is used in the same way as in the photonic semiconductor device according to the first embodiment, the photonic semiconductor device can be constructed using the P-type semiconductor substrate 10p in the same way as in the photonic semiconductor device according to the second embodiment.

The present invention is not limited to the above described embodiments, and numerous variants are possible. For instance, in the above described embodiments, an example is described in which the photonic semiconductor device is a semiconductor laser. However, the present invention is not limited to semiconductor lasers and can be applied in various other photonic semiconductor devices including optical modulators and optical amplifiers.

Moreover, although examples are described in which either the P-type electrode 28p or the N-type electrode 28n is electrically coupled to the upper part of the semiconductor layer 12 having the ridge part 14, the present invention can be widely applied whenever coupling an electrode of corresponding conductive type to the upper part of a ridge-form or mesa-form protruding part in a semiconductor layer. For instance, the present invention can be applied to a photonic semiconductor device having a structure known as a high-mesa structure in which an active layer is included in a semiconductor layer that has been processed to form a mesa-structure.

Further, the present invention can be applied in the case that the electrode couples to a protruding part produced by processing the upper part of contact layer 22, the upper cladding layer 20, the active layer 18 and the lower cladding layer 16 of the semiconductor layer 12 to a ridge-form or mesa-form.

Although examples are described in the above embodiment in which BCB resin is used as the material for the resin layer 26, the material of the resin layer 26 is not limited to being a BCB resin. Besides the BCB resin, a polyimide resin or the like can be used as the material for the resin layer 26.

Also, although examples are described in the above embodiment in which the semiconductor layer 12 includes the lower cladding layer 16 or the like, the layered construction of the semiconductor layer 12 is not limited to structures indicated in the above-described embodiments.

Moreover, although examples are described in the above embodiments in which the electrodes 28p and 28n and the pad electrode 32 are formed using the lift-off method, the present invention is not limited to the lift-off method for forming the electrodes, and various electrode forming methods can be used.

What is claimed is:

1. A photonic semiconductor device comprising:
a semiconductor layer having a ridge-form protruding part and formed over a semiconductor substrate;
a resin layer formed on surface parts of both sides of the protruding part so that the protruding part is embedded;
a first insulating layer including an opening that is formed on the resin layer and exposes an upper surface of the protruding part and a portion of a upper surface of the resin layer on both sides of the protruding part;
a first electrode formed in the opening to cover the upper surface of the protruding part, and electrically coupled to an upper part of the protruding part; and
a second electrode formed on the first electrode and the first insulation film, and electrically coupled to the first electrode.

2. The photonic semiconductor device according to claim 1, wherein
the second electrode is formed to cover the first electrode.

3. The photonic semiconductor device according to claim 1, wherein
the opening is formed in the first insulation film and the resin layer, and
the first electrode is formed on the bottom surface and the side surfaces of the opening.

4. The photonic semiconductor device according to claim 1, further comprising:
a second insulation film formed between the side surface parts of the protruding part and the resin layer.

5. The photonic semiconductor device according to claim 4, wherein
the first insulation film and the second insulation film have different etching characteristics.

6. The photonic semiconductor device according to claim 5, wherein
the first insulation film is a silicon nitride film, and
the second insulation film is a silicon oxide film.

7. The photonic semiconductor device according to claim 4, wherein
the first insulation film and the second insulation film have the same etching characteristics.

8. The photonic semiconductor device according to claim 7, wherein
the first insulation film and the second insulation film are one selected from a group consisting of silicon oxide film and silicon nitride film.

9. The photonic semiconductor device according to claim 1, wherein
the first electrode is alloyed with the upper part of the protruding part.

10. The photonic semiconductor device according to claim 1, wherein
a metal composition of the second electrode differs from a metal composition of the first electrode.

11. The photonic semiconductor device according to claim 1, wherein
the second electrode has as the lowermost layer a metal film that is adhesively bonded to the first insulation film.

12. The photonic semiconductor device according to claim 11, wherein
the metal film is at least one of the group consisting of a Ti film, a TiW film, an Ni film or a Cr film.

13. The photonic semiconductor device according to claim 1, wherein
the resin layer is made up of a BCB resin or a polyimide resin.

14. A manufacturing method for a photonic semiconductor device, comprising steps of:
forming, on a semiconductor substrate, a semiconductor layer having a ridge-form protruding part;
forming a resin layer on the semiconductor layer;
exposing an upper surface of the protruding part by etching the resin layer;
forming a first insulation film on the protruding part and the resin layer;
removing the first insulation film from an upper surface of the protruding part and from a portion of both sides of the protruding part of the resin layer;
forming a first electrode, which electrically couples to an upper part of the protruding part, on the protruding part and on portions of both sides of the protruding part of the resin layer, so as to cover the upper surface of the protruding part; and
forming a second electrode on the first electrode and the first insulation film, and electrically coupled to the first electrode.

15. The manufacturing method for the photonic semiconductor device according to claim 14, further comprising a step of:
forming a second insulation film on the semiconductor layer after the step of forming the semiconductor layer and before the step of forming the resin layer, wherein
in the step of exposing the upper surface of the protruding part, the upper surface of the protruding part is exposed by etching the resin layer and the second insulation film.

16. A manufacturing method for a photonic semiconductor device, comprising steps of:
forming on a semiconductor substrate a semiconductor layer having a ridge-form protruding part;
forming a resin layer on the semiconductor layer;
forming a first insulation film on the resin layer;
forming on the first insulation film and the resin layer an opening that reaches the protruding part and a portion of both sides of the protruding part of the resin layer;
forming, in the opening and so as to cover an upper surface of the protruding part, a first electrode electrically coupled to an upper part of the protruding part; and
forming, on the first electrode and the first insulation film, a second electrode that is electrically coupled to the first electrode.

17. The manufacturing method for the photonic semiconductor device according to claim 16, further comprising a step of
forming a second insulation film on the semiconductor layer after the step of forming the semiconductor layer and before the step of forming the resin layer, wherein
in the step of forming the opening, the opening is formed in the first insulation film, the resin layer, and the second insulation film.

18. The manufacturing method for the photonic semiconductor device according to claim 14, wherein
in the step of forming the second electrode, the second electrode is formed to cover the first electrode.
